(19) United States
(12) Patent Application Publication
(10) Pub. No.: US 2015/0043166 A1
(43) Pub. Date: Feb. 12, 2015

(54) OPTICAL TRANSMITTER MODULE WITH TEMPERATURE CONTROL DEVICE AND METHOD FOR MANUFACTURING THE SAME

(71) Applicant: Electronics and Telecommunications Research Institute, Daejeon (KR)

(72) Inventors: Young Soon HEO, Gwangju (KR); Hyun Seo KANG, Gwangju (KR); Keo-Sik KIM, Gwangju (KR); Young Sun KIM, Gwangju (KR); Jeong Eun KIM, Gwangju (KR); Hyoung Jun PARK, Gwangju (KR); Kwon Seob LIM, Gwangju (KR); Eun Kyoung JEON, Gwangju (KR)

(21) Appl. No.: 14/457,359

(22) Filed: Aug. 12, 2014

(30) Foreign Application Priority Data
Aug. 12, 2013 (KR) 10-2013-0095194

(51) Int. Cl. H05K 7/20; H04B 10/50

(52) U.S. Cl. CPC H05K 7/20509; H04B 10/503
USPC 361/704; 29/612

(57) ABSTRACT

The optical transmitter module may include a thermal-electric cooler comprising at least one metal pattern formed on a side of a cooling plate temperature of which is controlled by thermo-electric cooling elements, a laser diode installed in one of the at least one metal pattern, and a monitor photo diode which is installed in another one of the at least one metal pattern and monitors change of light signals emitted from the laser diode. Therefore, since elements are located on the same side of the cooling plate, the optical transmitter module may have a simple structure and an advantage that light signals emitted from the laser diode can be directly coupled to the optical fiber without optical path conversions. Also, since the laser diode is installed with a small gap from thermal-electric elements, the temperature control characteristics of the thermal-electric cooler can be enhanced.

### CLAIM FOR PRIORITY

This application claims priority to and the benefit of Korean Patent Application No. 10-2013-0095194 filed on Aug. 12, 2013 in the Korean Intellectual Property Office (KIPO), the entire contents of which are hereby incorporated by references.

### BACKGROUND

1. Technical Field

Example embodiments of the present invention relate to an optical transmitter module, and more specifically to an optical transmitter module controlling temperature by using thermo-electric cooling elements, and methods for manufacturing the same.

2. Related Art

According to advances of subscriber network technologies, a bandwidth demanded by subscribers is increasing. Also, the possibility of network congestion increases due to wide distribution of long-distance massive transmission technologies.

The optical communication technology started from a point-to-point communication and has become a core technology for the long-distance massive transmission domain owing to emergence of Erbium-doped fiber amplifiers and remarkable advances of optical communication elements. In addition, the results of studies in which a transmission rate such as several terabits per second is achieved are being announced. Also, products having at least several hundreds of gigabit per second transmission rate are being emerged in markets.

Especially, it is predicted that Metro Dense Wavelength Division Multiplexing (DWDM) systems will be used for regions in which cities are located densely, such as Korea and Europe, instead of long-haul transmission systems. Thus, it seems certain that a Wavelength Division Multiplexing (WDM) optical transmission system will perform a leading role according to world-wide technological trends of optical communication systems.

That is, although communications using Coarse Wavelength Division Multiplexing (CWDM) are performing main roles currently, they have only 16 channels due to limitation of available wavelengths, and deficiency of available channels is increasing demand for low-cost Transmitter Optical Subassembly (TOSA) for DWDM.

On the other hand, wavelength of optical signals generated by a laser diode used in the TOSA is affected by external temperature changes. Accordingly, deliberate controls on wavelength of optical signals generated by a laser diode which is used for application domains such as DWDM systems are needed. However, it is difficult to maintain temperature accurately by using only heat-sinks.

Therefore, for operations independent of external temperature environment, a thermo-electric cooler (thermo-electric cooler) and a temperature sensor may be used for accurately controlling temperature so as to minimize consumption of electrical power. Packaging in butterfly form or in ceramic form may be used for the optical module comprising a temperature control device. However, it requires high packaging costs.

Also, when a Transistor Outline (TO) can type packaging is used, an optical path of signals emitted from a laser diode should be converted by 90 degrees via a reflection minor in order to align the signal with an optical fiber. In this case, if the optical path is not converted by exact 90 degrees, there may be a problem of significantly decreased efficiency of optical coupling.

FIG. 1 is a view illustrating an optical module comprising a conventional temperature control device.

Referring to FIG. 1, illustrated is a laser diode package in which a thermo-electric cooler (thermo-electric cooler) 10 having structures 11 and 12 on which a laser diode 30, a thermistor 40, and a photo diode 50 are attached is attached to a TO base 20, and the laser diode 30 is attached on a side of the structure 11. Here, a light emission direction of the laser diode is vertical to a bottom plane of the base 30.

In the above-described optical module, although the laser diode can be installed on a L-shaped cooling plate of the thermo-electro cooler in order to package the optical module without optical path conversion, there may be a problem of degrading temperature control characteristics due to increased distance between the laser diode and the thermo-electric elements.

### SUMMARY

Accordingly, example embodiments of the present invention are provided to substantially obviate one or more problems due to limitations and disadvantages of the related art.

Example embodiments of the present invention provide an optical transmitter module which has a simple structure and is capable of controlling temperature.

Example embodiments of the present invention also provide methods for manufacturing an optical transmitter module which has a simple structure and is capable of controlling temperature.

In some example embodiments, an optical transmitter module may include a thermal-electric cooler comprising at least one metal pattern formed on a side of a cooling plate temperature of which is controlled by thermo-electric cooling elements; a laser diode installed in one of the at least one metal pattern; and a monitor photo diode which is installed in another one of the at least one metal pattern and monitors change of light signals emitted from the laser diode.

Here, the thermal-electric cooler may further comprise a thermistor which is installed in the other one of the at least one metal pattern and measures operating temperature of the laser diode controlled by the cooling plate. Also, the laser diode, the monitor photo diode, and the thermistor may be installed in a side of the cooling plate. Also, the thermo-electric cooler may be installed as facing a heat radiation plate.

Here, the thermal-electric cooler may further comprise a transistor outline (TO) cap including a lens used for focusing the light signals emitted from the laser diode. Also, a center of the TO cap may be configured to be coincided with a center of the lens. Also, the light signals emitted from the laser diode may be delivered to the lens without an optical path conversion.

Here, material of the at least one metal pattern may be gold (Au).

Here, a solder may be coated on the at least one metal pattern.

In other example embodiments, a method for manufacturing an optical transmitter module including a thermal-electric cooler having a laser diode, a monitor photo diode, a thermistor, and a cooling plate temperature of which is controlled by thermo-electric cooling elements, the method may comprises forming at least one metal pattern on a side of the cooling plate; installing the laser diode, the monitor photo diode, and the thermistor in the at least one metal pattern; and installing the thermal-electric cooler in the optical transmitter module as facing a heat radiation plate.

Here, the method may further comprise combining a transistor outline (TO) cap including a lens used for focusing light signals emitted from the laser diode. Also, a center of the TO cap may be configured to be coincided with a center of the lens. Also, the method may further comprise combining a receptacle embedding an optical fiber so that the light signals focused by the lens are delivered to the optical fiber.

Here, material of the at least one metal pattern may be gold (Au).

### BRIEF DESCRIPTION OF DRAWINGS

Example embodiments of the present invention will become more apparent by describing in detail example embodiments of the present invention with reference to the accompanying drawings, in which:

FIG. 1 is a view illustrating an optical module comprising a conventional temperature control device;

FIG. 2 is an oblique view illustrating a thermo-electric cooler on which at least one metal pattern is formed according to an example embodiment of the present invention;

FIG. 3 is an oblique view illustrating a thermo-electric cooler on which elements are installed according to an example embodiment of the present invention;

FIG. 4 is an oblique view illustrating a TO stem of an optical transmitter module in which the thermo-electric cooler according to the present invention is installed;

FIG. 5 is a plane view illustrating a TO stem of an optical transmitter module in which the thermo-electric cooler according to the present invention is installed;

FIG. 6 is an oblique view illustrating a TO cap 300 combined with the TO stem 200 according to an example embodiment of the present invention;

FIG. 7 is a sectional view to explain an operation of an optical transmitter module according to an example embodiment of the present invention; and

FIG. 8 is a flow chart illustrating a method for manufacturing an optical transmitter module according to an example embodiment of the present invention.

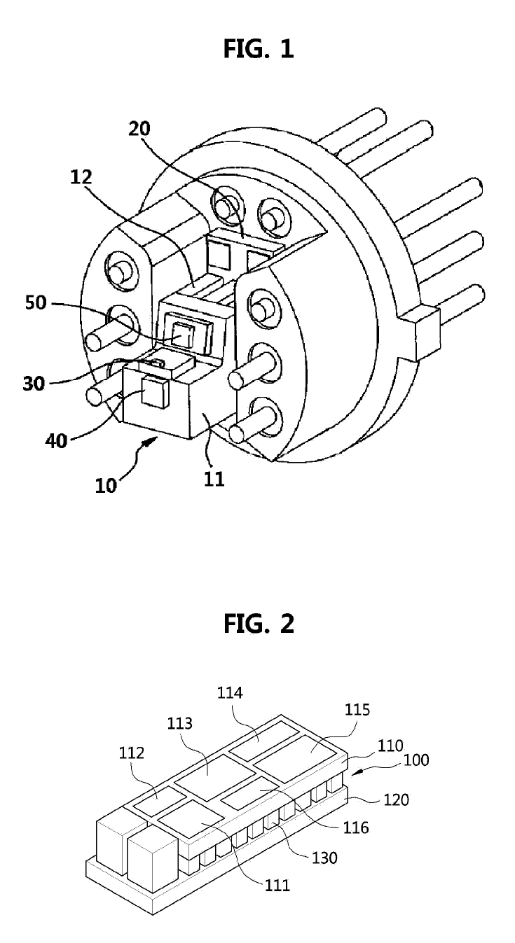

### DESCRIPTION OF EXAMPLE EMBODIMENTS

Example embodiments of the present invention are disclosed herein. However, specific structural and functional details disclosed herein are merely representative for purposes of describing example embodiments of the present invention, however, example embodiments of the present invention may be embodied in many alternate forms and should not be construed as limited to example embodiments of the present invention set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, preferred example embodiments according to the present invention will be explained in detail by referring to accompanying figures.

First, terms used in this specification will be briefly explained as follows.

A thermo-electric element is an element controlling temperature by using heat absorption and heat radiation phenomenon due to Peltier effects. It comprises a plurality of n-type and p-type semiconductors which are electrically connected in serial and thermally connected in parallel, and insulated by two ceramic plates such as Aluminum Oxide (Al₂O₃) or aluminum nitride (AlN). That is, when a direct current (DC) is applied to it, according to electrons delivered from lower energy level of p-type to higher energy level of n-type, heat is absorbed in a cold junction. Also, heat is radiated to a heat sink at a hot junction. Heat generated in the thermo-electric element may be radiated out through heat-conductive materials or a base in which thermo-electric cooler are installed. Here, the ceramic plate may use solders or epoxy having good heat transfer characteristics, in order to make control of temperature easier when a laser diode and a thermistor are populated on it.

The thermistor may be a semiconductor element having a characteristic that an electrical resistance value of it decreases sensitively to increase of temperature.

The present invention relates to a transistor outline (TO) type laser diode package embedding a thermo-electric cooler having thermo-electric elements.

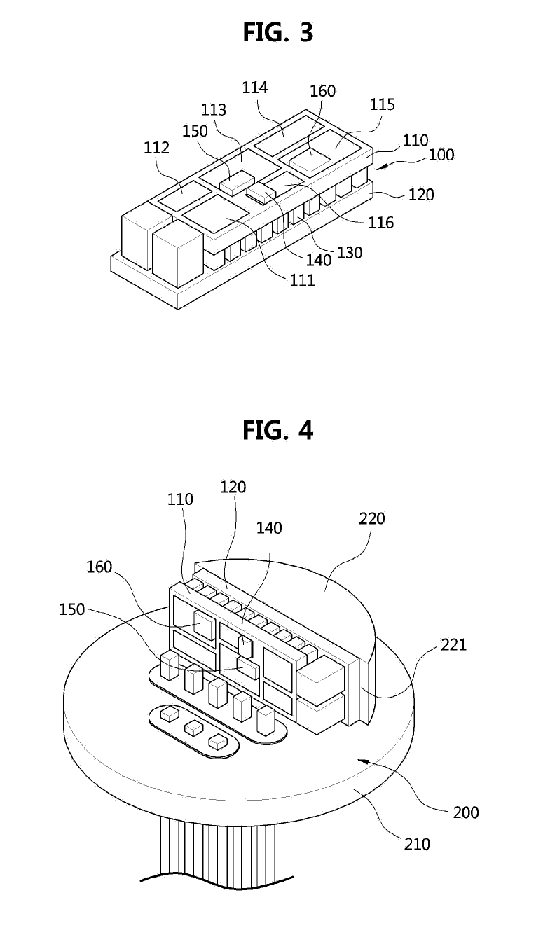

FIG. 2 is an oblique view illustrating a thermo-electric cooler on which at least one metal pattern is formed according to an example embodiment of the present invention, and FIG. 3 is an oblique view illustrating a thermo-electric cooler on which elements are installed according to an example embodiment of the present invention.

Referring to FIG. 2, a thermo-electric cooler 100 which is installed in an optical transmitter module according to the present invention may include a plurality of metal patterns.

Specifically, the thermo-electric cooler 100 may be configured as including a cooling plate 110, thermo-electric elements 130, and a heating plate 120. For example, in the thermo-electric cooler 100, the thermo-electric elements 130 are located between the cooling plate 110 and the heating plate 130. That is, the cooling plate 110 and the heating plate 120 are connected by the thermo-electric elements 130.

A plurality of metal patterns 111, 112, 113, 114, 115, and 116 may be formed on a side of the cooling plate 110 of the thermo-electric cooler 100. Referring to FIG. 2, six metal patterns 111 to 116 may be formed on a side of the cooling plate 110, each having a rectangular form. However, the number of metal patterns and shape of them are not restricted to the above example.

Especially, material of the metal patterns 111 to 116 which are formed on the cooling plate 110 may be gold (Au), and a solder may be further coated (evaporated or deposited) on a specific metal pattern among them. For example, a solder may be coated on the metal pattern 116 on which the laser diode 140 is installed.

Referring to FIG. 3, elements are installed on the metal patterns 113, 115, and 116 formed on the same side of the cooling plate 110. That is, the laser diode 140 may be installed on one (e.g. 116) of the metal patterns, and a photo diode 150 may be installed on another one (e.g. 113) of the metal patterns. Also, a thermistor 160 may be installed on the other one (e.g. 115) of the metal patterns.

The laser diode 140 installed in the thermo-electric cooler 100 may emit light signals, and the monitor photo diode (mPD) 150 may be able to monitor the light signals emitted from the laser diode 140 by measuring change of the light signals. That is, the monitor photo diode 150 may monitor change of the light signals emitted from the laser diode 140 whereby it can identify change in characteristics of the laser diode 140.

Also, the thermistor 160 installed in the thermo-electric cooler 100 may provide measurement result of temperature controlled by the thermo-electric cooler 100. That is, the thermistor 160 may measure operating temperature of the laser diode which is controlled by the thermo-electric cooler 100 thereby maintaining the operating temperature of the laser diode 140 as a preconfigured temperature.

Referring to FIG. 2 and FIG. 3, according to an example embodiment of the present invention, the laser diode 140, the monitor photo diode 150, and the thermistor 160 are located on the same side of the cooling plate 110 whereby they can be installed without using an additional sub-mount structure.

Also, the laser diode 140 is installed directly on the side of the cooling plate 110 of the thermo-electric cooler 100 so that the distance between the laser diode 140 and the thermo-electric cooling elements 130 can be minimized. Accordingly, the problem of degrading temperature control characteristics of the laser diode 140 due to the increased distance between the laser diode 140 and the thermo-electric cooling elements 130 may be resolved.

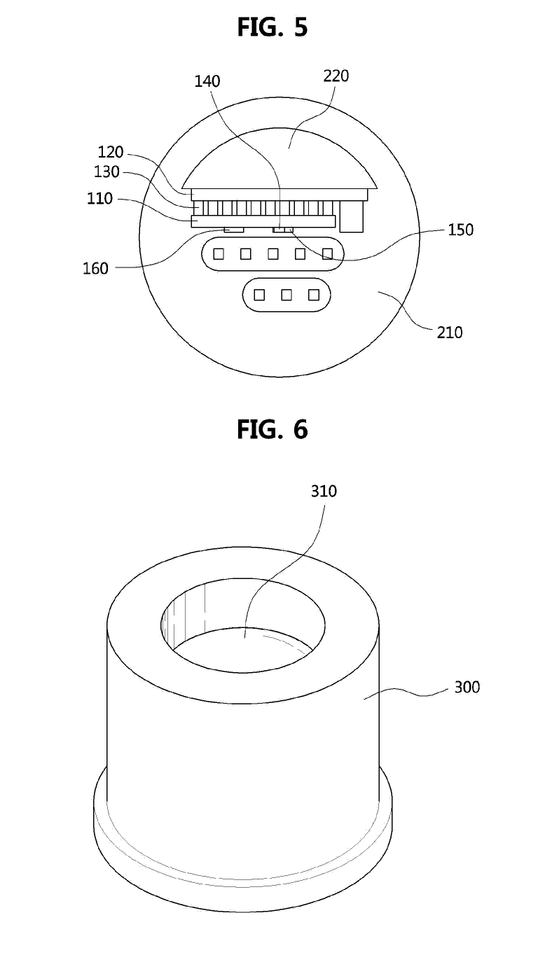

FIG. 4 is an oblique view illustrating a TO stem of an optical transmitter module in which the thermo-electric cooler according to the present invention is installed, and FIG. 5 is a plane view illustrating a TO stem of an optical transmitter module in which the thermo-electric cooler according to the present invention is installed.

Referring to FIG. 4 and FIG. 5, the TO stem 200 constituting the optical transmitter module according to the present invention may comprise a TO base 210 and a TO header 220.

The TO base 210 may have a form of a circular plate, and the TO header 220 may have a semi-circular cylinder shape. Also, the thermo-electric cooler 100 according to the present invention may be installed on the TO header 220. Also, the TO header 220 may be installed vertically on the TO base 210. However, shapes of the TO base 210 and TO header 220 are not restricted to the above example. The TO base 210 and the TO header 220 may be made of metallic material having good thermal conductivity.

The thermo-electric cooler 100 may be installed in the TO stem 200 as facing a side of the TO header 220 installed vertically on the TO base 210. Here, the side of the TO header 220 which faces the thermo-electric cooler 100 may be referred to as a heat radiation plate 221. That is, the heating plate 120 of the thermo-electric cooler 100 is combined with the heat radiation plate 221 as facing the heat radiation plate 221, and so heat generated by the heating plate 120 may be radiated through the TO header 220 and the TO base 210.

The optical transmitter module according to the present invention, in which the thermo-electric cooler 100 comprising the laser diode 140, the monitor photo diode 150, and the thermistor 160 is installed, will be explained in further detail as follows.

In order to constantly maintain output wavelength of the laser diode 140, it is necessary to perform temperature control on the laser diode 140. Thus, in the present invention, the laser diode 140, the monitor photo diode 150, and the thermistor 160 may be installed on the same side of the cooling plate 110 of the thermo-electric cooler 100.

Also, patterns 111 to 116 using material (e.g. Au) with good thermal conductivity may be formed on the side of the cooling plate 110. In addition, a solder may be coated further on the specific pattern 116.

The patterns on which the laser diode 140, the monitor photo diode 150, and the thermistor 160 are installed are wire-bonded to lead pins of the TO stem 200.

If the temperature of the laser diode 140 varies, light power may vary and so wavelength of the light emitted from the laser diode 140 may vary. Thus, the monitor photo diode may identify change of characteristics of the laser diode 140 by monitoring change of light signals emitted from the laser diode 140.

The thermistor 160 may measure operating temperature of the laser diode and provide the measurement result in order to maintain the operating temperature of the laser diode 140.

Meanwhile, according to the present invention, patterns 111 to 116 are coated (evaporated or deposited) on the same side of the cooling plate 110 of the thermo-electric cooler 100, and the laser diode 140, the monitor photo diode 150, and the thermistor 160 are installed on them so that an additional sub-mount is not necessary.

Also, since the laser diode 140 is installed directly on the cooling plate 110 of the thermo-electric cooler 100, temperature control characteristics of the laser diode 140 become superior and a packaging procedure may be simplified.

The TO header 220 may have a semi-circular cylinder shape so that the thermo-electric cooler 100 may be installed on it. Thus, it becomes possible to locate the laser diode 140 in a center of the TO base 210, and the laser diode 140 can be installed so that the length of wire-bonding between the laser diode 140 and corresponding lead pins becomes short.

For example, glass sealing may be performed on lead pins (e.g. 8 pins). Two lead pins may respectively be wire-bonded to each of the laser diode 140, the monitor photo diode 150, and the thermistor 160. In addition, the other two lead pins may be wire-bonded to the thermo-electric elements 130.

Since heat is radiated from the heating plate 120 of the thermo-electric cooler 100, material having good thermal conductivity may be used for the TO header 220 and the TO base 210 which are combined with the thermo-electric cooler 100.

For example, since the thermo-electric cooler 100 is installed on the heat radiation plate 221 of the TO header 220 having a semi-circular cylinder shape, light signals emitted from the laser diode 140 may be directly coupled to the optical fiber without optical path conversion.

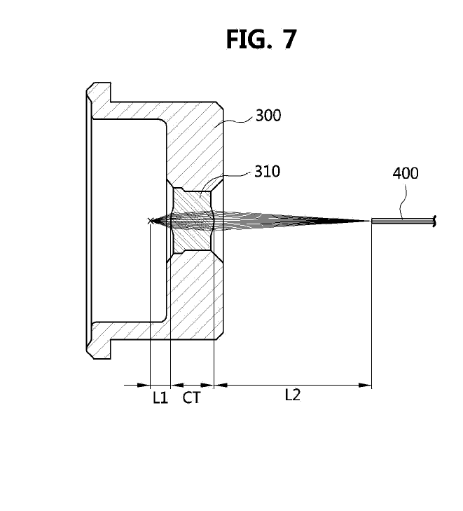

FIG. 6 is an oblique view illustrating a TO cap 300 combined with the TO stem 200 according to an example embodiment of the present invention, and FIG. 7 is a sectional view to explain an operation of an optical transmitter module according to an example embodiment of the present invention.

The optical transmitter module according to the present invention may be configured with a combination of the TO stem 200 and the TO cap 300. That is, the optical transmitter module may be configured as a form in which the TO cap 300 covers the TO stem 200 in which the thermo-electric cooler 100 is installed.

Referring to FIG. 6, the TO cap 300 may include a lens 310 used for focusing light signals emitted from the laser diode 140.

Generally, the TO cap 300 uses a window glass. However, in order not to use an additional sub-mount or a structure for fixing a window glass, in the present invention, the lens 310 may be used instead of the window glass so that the size of the optical transmitter module may be reduced without using additional parts.

Especially, the laser diode 140 of the thermo-electric cooler 100 may become aligned to a center of the TO base 210, and a center of the TO cap 300 may become coincided with a center of the lens 310. Thus, light signals emitted from the laser diode 140 can be configured to pass through the center of the lens 310. That is, it becomes not necessary to additionally align the signals of the laser diode 140 to the lens 310.

Referring to FIG. 7, the optical transmitter module according to an example embodiment of the present invention may be manufactured so that a gap between the laser diode 140 and the lens 310 becomes short.

Specifically, the laser diode 140 may be located with a gap L1 from the lens 310 along a center axis of the lens 310, and the optical fiber 400 may be located with a gap L2 from the lens 310 along the center axis of the lens 310. Also, CT may mean a thickness of the lens 310.

In the conventional optical transmitter module, since L1 and L2 have a very little difference, numerical aperture (NA) of the light signals focused by the lens 310 becomes similar to NA of the optical fiber 400. Accordingly, even a small tilt generated in the light signals emitted from the laser diode may cause significant degradation of optical coupling efficiency.

However, in the optical transmitter module according to the present invention, the difference between L1 and L2 may become greater as compared to the conventional one by configuring the gap between the laser diode 140 and the lens 310 as short so that NA of the light signals focused by the lens 310 can become smaller than NA of the optical fiber 400. Therefore, even when a tilt is generated in the light signals emitted from the laser diode 140, significant degradation of optical coupling efficiency may be prevented.

The following table 1 represents simulated values of optical coupling efficiency when each of L1, L2, and CT is respectively set to 0.5 mm, 2.44 mm, and 1 mm and when a pigtail optical fiber is used as the optical fiber.

From the table 1, it can be known that significant degradation of optical coupling efficiency can be prevented even when a tilt is generated in the light signals emitted from the laser diode 140.

TABLE 1

| Tilt (degrees) | Optical coupling efficiency |
|---|---|
| −20 | 62% |
| −15 | 72% |
| −10 | 73% |
| −4 | 73% |
| 0 | 73% |
| 4 | 73% |
| 10 | 73% |
| 15 | 72% |
| 20 | 64% |

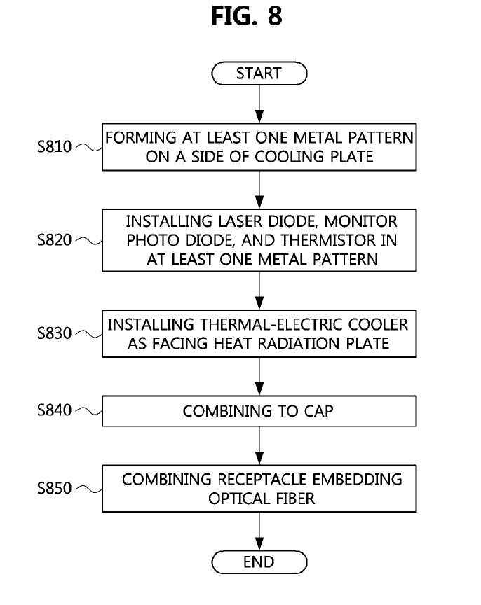

FIG. 8 is a flow chart illustrating a method for manufacturing an optical transmitter module according to an example embodiment of the present invention.

Referring to FIG. 8, the manufacturing method of the optical transmitter module according to the present invention may comprise a step S810 of forming at least one metal pattern, a step S820 of installing the laser diode, the monitor photo diode, and the thermistor on the at least one metal pattern, a step S830 of installing the thermal-electric cooler as facing a heat radiation plate, a step S840 of combining a TO cap, and a step S850 of combining a receptacle embedding an optical fiber.

At least one metal pattern may be formed on a side of a cooling plate 110 of the thermal electric cooler 100 (S810). The thermal electric cooler 100 may comprise the cooling plate 110, thermo-electric elements 130, and the heating plate 120. Also, the cooling plate 110 and the heating plate 120 may be connected via the thermo-electric elements 130.

For example, a plurality of metal patterns 111, 112, 113, 114, 115, and 116 may be formed on a side of the cooling plate 110 of the thermo-electric cooler 100, each having a rectangular form. Also, material for the metal patterns 111 to 116 which are formed on the cooling plate 110 may be gold (Au), and a solder may be further coated (evaporated or deposited) on a specific metal pattern among a plurality of metal patterns.

The laser diode 140, the monitor photo diode 150, and the thermistor 160 may be installed on the metal patterns (S820). That is, the laser diode 140 may be installed on one (e.g. 116) of the metal patterns, and the monitor photo diode 150 may be installed on another one (e.g. 113) of the metal patterns. Also, the thermistor 160 may be installed on the other one (e.g. 115) of the metal patterns. In other words, the laser diode 140, the monitor photo diode 150, and the thermistor 160 are located on the same side of the cooling plate 110 whereby the optical transmitter module may be manufactured without an additional sub-mount structure. Also, the laser diode 140 is installed directly on the side of the cooling plate 110 of the thermo-electric cooler 100 so that the distance between the laser diode 140 and the thermo-electric cooling elements 130 can be minimized.

Here, the laser diode 140 installed in the thermo-electric cooler 100 may emit light signals, and the monitor photo diode 150 may be able to monitor the light signals emitted from the laser diode 140 by measuring change of the light signals.

Also, the thermistor 160 installed in the thermo-electric cooler 100 may provide results of measurement on operating temperature of the laser diode 140. That is, the thermistor 160 may measure operating temperature of the laser diode 140 thereby maintaining the operating temperature of the laser diode 140 as a preconfigured temperature.

The thermo-electric cooler 100 in which the laser diode 140, the monitor photo diode 150, and the thermistor 160 are installed may be installed in the TO stem so that the thermo-electric cooler 100 faces the heat radiation plate of the TO header (S830).

Specifically, in the optical transmitter module according to the present invention, the thermo-electric cooler 100 may installed in the TO stem 200 comprising the TO base 210 and the TO header 220. The thermo-electric cooler 100 may be installed in the TO stem 200 as facing a side of the TO header 220 installed vertically on the TO base 210.

Here, the side of the TO header 220 which faces the thermo-electric cooler 100 may be referred to as a heat radiation plate 221. That is, the heating plate 120 of the thermo-electric cooler 100 is combined with the heat radiation plate 221 as facing the heat radiation plate 221, and so heat generated by the heating plate 120 may be radiated through the TO header 220 and the TO base 210. Accordingly, material having good thermal conductivity may be used for the TO header 220 and the TO base 210.

In order to constantly maintain output wavelength of the laser diode 140, it is necessary to perform temperature control on the laser diode 140. Thus, in the present invention, the laser diode 140, the monitor photo diode 150, and the thermistor 160 may be installed on the same side of the cooling plate 110 of the thermo-electric cooler 100.

For example, the TO header 220 may have a semi-circular cylinder shape so that the thermo-electric cooler 100 may be installed on it. Also, it becomes possible to locate the laser diode 140 in a center of the TO base 210. Also, the laser diode 140 can be installed so that the length of wire-bonding between the laser diode 140 and lead pins becomes short.

Therefore, since the thermo-electric cooler 100 is installed on the heat radiation plate 221 of the TO header 220 having a semi-circular cylinder shape, optical signals emitted from the laser diode 140 may be directly coupled to the optical fiber without optical path conversion.

The TO cap 300 including the lens 310 for focusing light signals emitted from the laser diode 140 can be combined (S840). Since the optical transmitter module according to the present invention may be configured with a combination of the TO stem 200 and the TO cap 300, the optical transmitter module may be configured as a form in which the TO stem 200 embedding the thermo-electric cooler 100 covers the TO cap 300.

The laser diode 140 of the thermo-electric cooler 100 may become aligned to the center of the TO base 210, and the center of the TO cap 300 may become coincided with the center of the lens 310. Thus, signals emitted from the laser diode 140 can be configured to pass through the center of the lens 310.

Also, a receptacle (not illustrated) embedding 400 optical fiber 400 may be combined in order to make the light signals focused by the lens 310 be transferred to the optical fiber 400 (S850). For example, the receptacle which embeds the optical fiber 400 so as to locate the optical fiber 400 in the center axis of the lens 310 may be combined through a laser welding.

According to the optical transmitter module and the method for manufacturing the same, the laser diode 140, the monitor photo diode 150, and the thermistor 160 are located on the same side of the cooling plate 110 of the thermal-electric cooler 100, whereby the optical transmitter module may be manufactured without an additional sub-mount structure.

Also, since the thermal-electric cooler 100 is installed in the TO stem having a side heat radiation structure, the optical transmitter module according to the present invention may have a simple structure and an advantage that light signals emitted from the laser diode 140 may be directly coupled to the optical fiber without optical path conversions.

Also, since the laser diode is installed with a small gap from thermal-electric elements, the temperature control characteristics of the thermal-electric cooler 100 may be enhanced.

While the example embodiments of the present invention and their advantages have been described in detail, it should be understood that various changes, substitutions and alterations may be made herein without departing from the scope of the invention.

What is claimed is:

1. An optical transmitter module including a thermal-electric cooler, the thermal-electric cooler comprising:
at least one metal pattern formed on a side of a cooling plate temperature of which is controlled by thermo-electric cooling elements;
a laser diode installed in one of the at least one metal pattern; and
a monitor photo diode which is installed in another one of the at least one metal pattern and monitors change of light signals emitted from the laser diode.

2. The optical transmitter module of claim 1, further comprising a thermistor which is installed in the other one of the at least one metal pattern and measures operating temperature of the laser diode controlled by the cooling plate.

3. The optical transmitter module of claim 2, wherein the laser diode, the monitor photo diode, and the thermistor are installed in a side of the cooling plate.

4. The optical transmitter module of claim 2, wherein the thermo-electric cooler is installed as facing a heat radiation plate.

5. The optical transmitter module of claim 1, further comprising a transistor outline (TO) cap including a lens used for focusing the light signals emitted from the laser diode.

6. The optical transmitter module of claim 5, wherein a center of the TO cap is configured to be coincided with a center of the lens.

7. The optical transmitter module of claim 5, wherein the light signals emitted from the laser diode are delivered to the lens without an optical path conversion.

8. The optical transmitter module of claim 1, wherein material of the at least one metal pattern is gold (Au).

9. The optical transmitter module of claim 1, wherein a solder is coated on the at least one metal pattern.

10. A method for manufacturing an optical transmitter module including a thermal-electric cooler having a laser diode, a monitor photo diode, a thermistor, and a cooling plate temperature of which is controlled by thermo-electric cooling elements, the method comprising:
forming at least one metal pattern on a side of the cooling plate;
installing the laser diode, the monitor photo diode, and the thermistor in the at least one metal pattern; and
installing the thermal-electric cooler in the optical transmitter module as facing a heat radiation plate.

11. The method of claim 10, further comprising combining a transistor outline (TO) cap including a lens used for focusing light signals emitted from the laser diode.

12. The method of claim 11, wherein a center of the TO cap is configured to be coincided with a center of the lens.

13. The method of claim 11, further comprising combining a receptacle embedding an optical fiber so that the light signals focused by the lens are delivered to the optical fiber.

14. The method of claim 10, wherein material of the at least one metal pattern is gold (Au).
